(19) United States
(12) Patent Application Publication
(10) Pub. No.: US 2004/0258958 A1
(43) Pub. Date: Dec. 23, 2004

(54) Organic electroluminescent device

(76) Inventors: Tung-Sheng Cheng, Hsinchu (TW); Ming Chung Shih, Jubei City (TW); Kuen Yi Lin, Shinjuang City (TW)

Correspondence Address: BIRCH STEWART KOLASCH & BIRCH, PO BOX 747, FALLS CHURCH, VA, 22040-0747, US

(21) Appl. No.: 10/870,039

(22) Filed: Jun. 18, 2004

(30) Foreign Application Priority Data
Jun. 20, 2003 (TW) 092116902

(51) Int. Cl. H05B 33/12

(52) U.S. Cl. 428/690; 428/917; 428/138; 313/504; 313/506; 257/88

(57) ABSTRACT

An organic electroluminescent device comprises a transparent substrate, a first electrode, a hole buffer layer, an organic electroluminescent layer, and a second electrode. In this case, the first electrode is disposed on the transparent substrate. The hole buffer layer comprises a surface-activation agent and is disposed on the first electrode. The organic electroluminescent layer is disposed on the hole buffer layer. The second electrode is disposed on the organic electroluminescent layer.

### BACKGROUND OF THE INVENTION

1. Field of Invention

The invention relates to an organic electroluminescent device and, in particular, to an organic electroluminescent device having a hole buffer layer.

2. Related Art

The organic electroluminescent devices may become the major choice for flat panel display technology in the future since organic electroluminescent devices possess the advantages of self-luminescence, wide viewing angle, high power efficiency, easier manufacture process, low cost, rapid response rate, and full color.

The present organic electroluminescent device is mainly consisted of a transparent substrate, a transparent anode, an organic functional layer, a cathode, and a separating portion. The transparent anode, organic functional layer, and cathode are disposed on the transparent substrate in sequence. The separating portion is disposed on the transparent anode for dividing the organic functional layer into a plurality of pixels. Herein, the organic functional layer comprises a hole buffer layer, an organic light-emitting layer and an electron buffer layer.

When applying a current to the organic electroluminescent device, holes are injected from the transparent anode into the organic functional layer while electrons are injected from the cathode. Based on the applied voltage, the holes and electrons are moved in the organic functional layer, and are recombined to generate excitons. The excitons can excite materials of the organic functional layer, and the excited materials can then emit light to release energy.

As shown in FIG. 1, when the transparent anode 32 and the hole buffer layer 33 are formed on the transparent substrate 31 in sequence, the planarity of each layer is a critical point. However, when forming the hole buffer layer 33 on the transparent anode 32, the part of the hole buffer layer 33 close to the separating portion 34 is thicker than other part thereof due to the surface tension of the hole buffer layer 33 is too large. In other words, the thickness of the hole buffer layer 33 is decreased progressively from the part close to the separating portion 34 (position A) to the central part (position B). Therefore, the planarity of the hole buffer layer 33 can not conform to the requirements, resulting in the unqualified uniformity of the brightness of the organic electroluminescent device. Moreover, the production yield of the organic electroluminescent device is decreased.

It is therefore a subjective to provide an organic electroluminescent device, which can solve the above-mentioned problems.

### SUMMARY OF THE INVENTION

In view of the foregoing, the invention is to provide an organic electroluminescent device having a hole buffer layer with good planarity.

To achieve the above, an organic electroluminescent device of the invention comprises a transparent substrate, a first electrode, a hole buffer layer, an organic electroluminescent layer, and a second electrode. In this invention, the first electrode is disposed on the transparent substrate. The hole buffer layer comprises a surface-activation agent and is disposed on the first electrode. The organic electroluminescent layer is disposed on the hole buffer layer. The second electrode is disposed on the organic electroluminescent layer.

To achieve the above, an electrode substrate of the invention comprises a transparent substrate, an electrode layer, and a hole buffer layer. In this invention, the electrode layer is disposed above the transparent substrate. The hole buffer layer is disposed above the electrode layer.

Herein, the organic electroluminescent devices include a small molecule OLED (SM-OLED) and a polymer light-emitting device (PLED).

As mentioned above, the organic electroluminescent device of the invention comprises the hole buffer layer, which comprises a surface-activation agent. Comparing to the prior art, the invention can reduce the surface tension of the hole buffer layer. When forming the hole buffer layer on the first electrode, the surface-activation agent can enhance the planarity of the hole buffer layer. Thus, the uniformity of the brightness of the organic electroluminescent device is improved, and the production yield of the organic electroluminescent device is increased. In addition, the invention is suitable for mass production since the manufacturing process is simpler and cheaper.

### BRIEF DESCRIPTION OF THE DRAWINGS

The invention will become more fully understood from the detailed description given hereinbelow illustration only, and thus is not limitative of the present invention, and wherein:

FIG. 1 is a schematic view showing a conventional electrode substrate;

FIG. 2 is a schematic view showing an organic electroluminescent device according to a first embodiment of the invention; and

FIG. 3 is a schematic view showing an organic electroluminescent device according to a second embodiment of the invention.

### DETAILED DESCRIPTION OF THE INVENTION

The present invention will be apparent from the following detailed description, which proceeds with reference to the accompanying drawings, wherein the same references relate to the same elements.

With reference to FIG. 2, an organic electroluminescent device 1 according to the first embodiment of the invention comprises a transparent substrate 11, a first electrode 12, a hole buffer layer 13, an organic electroluminescent layer 14, and a second electrode 15. In this embodiment, the first electrode 12 is disposed on the transparent substrate 11. The hole buffer layer 13 comprises a surface-activation agent and is disposed on the first electrode 12. The organic electroluminescent layer 14 is disposed on the hole buffer layer 13. The second electrode 15 is disposed on the organic electroluminescent layer 14.

In the current embodiment, the transparent substrate 11 can be a flexible or rigid substrate. The transparent substrate 11 can also be a plastic or glass substrate. In particular, the flexible substrate or plastic substrate can be made of polycarbonate (PC), polyester (PET), cyclic olefin copolymer (COC), or metallocene-based cyclic olefin copolymer (mCOC).

Referring to FIG. 2, the first electrode 12 is disposed on the transparent substrate 11. In the present embodiment, the first electrode 12 is formed on the transparent substrate 11 by a sputtering method or an ion plating method. The first electrode 12 may be used as an anode and made of a transparent electric conductive metal oxide, such as indium-tin oxide (ITO), aluminum-zinc oxide (AZO), or indium-zinc oxide (IZO).

Furthermore, the hole buffer layer 13 in the current embodiment is disposed on the first electrode 12 and comprises a surface-activation agent. The hole buffer layer 13 may comprise a hole-injecting layer or a hole-transporting layer. Alternatively, the hole buffer layer 13 may comprise both of the hole-injecting layer and hole-transporting layer. Herein, the material of the hole buffer layer 13 can be a conductive polymeric material, which comprises and is not limited to poly(3,4-ethylenedioxythiophene) (PEDOT), polyaniline (PANI), or poly(N-vinylcarbazole) (PVK). Of course, the material of the hole buffer layer 13 can be a conductive small molecule material, which comprises and is not limited to copper phthalocyanine (CuPc), 4,4′,4′-tris(1-naphthylphenylamino)triphenylamine (1-TNATA), 4,4′,4″-tris-N-3-methylphenyl-N-phenyl-amino)-triphenylamine (m-MTDATA), 4,4′-bis[N-(1-naphthyl)-N-phenylamino]biphenyl (NPB), 4,4′-bis[N-(3-methylphenyl)-N-phenyl-amino]-biphenyl (TPD), triphenylamine tetramer (TPTE), spiro-linked TAD (spiro-TAD), 1,1-bis(4-di-p-tolylaminophenyl)-4-phenylcyclohexane (TPAC), or 2,5-diphenyl-1,3,4-oxadiazole (PPD).

In addition, the surface-activation agent can be an anion surface-activation agent, a cation surface-activation agent, an amphoteric surface-activation agent, or a nonionic surface-activation agent. In the embodiment, the chemical formula of the anion surface-activation agent can be RCOOM or RSO₃M, which comprises and is not limited to acetate compounds or sulfate compounds. Wherein, R can be alkyl or phenyl, and M can be metal ion, which comprises and is not limited to alkaline metal or alkaline-earth metal. The cation surface-activation agent comprises and is not limited to organic amine salts or quaternary amine salts. The chemical formula of the nonionic surface-activation agent comprises and is not limited to (RO—(CH₂CH₂O)ₙ—H), the copolymer thereof, RO—(CH(CH₃)CH₂O)ₙ—H and the copolymer thereof. The chemical formula of the amphoteric surface-activation agent can be RR′C(NH₂)COOH or RR′C(NH₂)SO₃H, which comprises and is not limited to amino acid. Wherein, R and R′ can be alkyl or phenyl. In this case, the hydrophile-lipophile balance (HLB) value of the surface-activation agent is greater than or equal to 8.

The hole buffer layer 13 can be formed upon the first electrode 12 by utilizing spin coating, ink jet printing, or printing.

Referring to FIG. 2, the organic electroluminescent layer 14 of the embodiment is disposed on the hole buffer layer 13. Herein, the organic electroluminescent layer 14 can be formed upon the hole buffer layer 13 by utilizing evaporation, spin coating, ink jet printing, or printing. In addition, the light emitted from the organic electroluminescent layer 14 can be blue, green, red, white or other monochromatic lights, or mixed monochromatic lights.

With reference to FIG. 2, the second electrode 15 is formed on the organic electroluminescent layer 14 by way of evaporation or sputtering. The material of the second electrode 15 can be one selected from and not limited to the group consisting of aluminum (Al), calcium (Ca), magnesium (Mg), indium (In), tin (Sn), manganese (Mn), silver (Ag), gold (Au), and magnesium alloys, such as magnesium-silver alloys, magnesium-indium alloys, magnesium-tin alloys, magnesium-antimony alloys, and magnesium-tellurium alloys.

Furthermore, the organic electroluminescent device 1 of the embodiment may further comprise an electron buffer layer (not shown). Herein, the electron buffer layer may further comprise an electron-transporting layer or an electron-injecting layer. Of course, the electron buffer layer may comprise both of the electron-transporting layer and electron-injecting layer. In the present embodiment, the electron buffer layer is disposed on the organic electroluminescent layer 14. Herein, the material of the electron buffer layer is one mainly selected from the group consisting of alkaline metal, alkaline-earth metal, lanthanide metal, alkaline metal halide, alkaline-earth metal halide, and lanthanide metal halide. The alkaline metal comprises and is not limited to lithium or sodium. The alkaline-earth metal comprises and is not limited to magnesium, barium or calcium. The lanthanide metal comprises and is not limited to samarium (Sm), thulium (Tm), terbium (Tb), or Ytterbium (Yb). The alkaline metal halide comprises and is not limited to lithium fluoride (LiF), sodium fluoride (NaF), or cesium fluoride (CsF). The alkaline-earth metal halide comprises and is not limited to magnesium fluoride (MgF₂), barium fluoride (BaF₂), or calcium fluoride (CaF₂). The lanthanide metal halide comprises and is not limited to samarium iodide (SmI₂). The material of the electron buffer layer can also be tris(8-quinolinato-N1,08)-aluminum (Alq₃).

In addition, the organic electroluminescent device 1 of the embodiment may further comprise a separating portion 16, which is disposed on the first electrode 12. As shown in FIG. 2, the separating portion 16 divides the hole buffer layer 13 and the organic electroluminescent layer 14 into a plurality of pixels. In other words, the separating portion 16 divides the organic functional layer into a plurality of pixels and is black for shielding or reflecting light. This could avoid the light mixing from the pixels, and control the direction of the light and increasing the utilization and uniformity of light. Herein, the material of the separating portion 16 is one selected from and is not limited to the group consisting of polyimide, novolak resin, amines as curing agent in epoxy resins, anhydrides as curing agent in epoxy resins, acrylics and polyamide.

In the embodiment, the organic electroluminescent device 1 can be a small molecule OLED (SM-OLED) or a polymer light-emitting device (PLED).

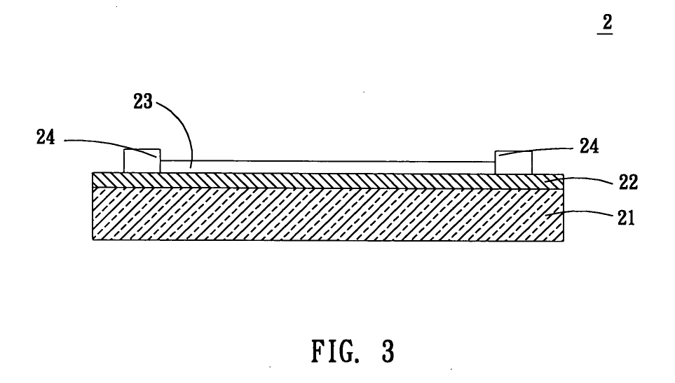

With reference to FIG. 3, an electrode substrate 2 according to a second embodiment of the invention comprises a transparent substrate 21, an electrode layer 22, and a hole buffer layer 23. In the embodiment, the electrode layer 22 is disposed above the transparent substrate 21, and the hole buffer layer 23 is disposed above the electrode layer 22.

Since the features and functions of the transparent substrate 21, electrode layer 22 and hole buffer layer 23 in the second embodiment are the same as those of the transparent substrate 11, electrode layer 12 and hole buffer layer 13 in the first embodiment, they are not repeatedly described hereinafter.

In addition, the features and functions of the separating portion 24 in the second embodiment are the same as those of the separating portion 16 in the first embodiment, they are not repeatedly described hereinafter.

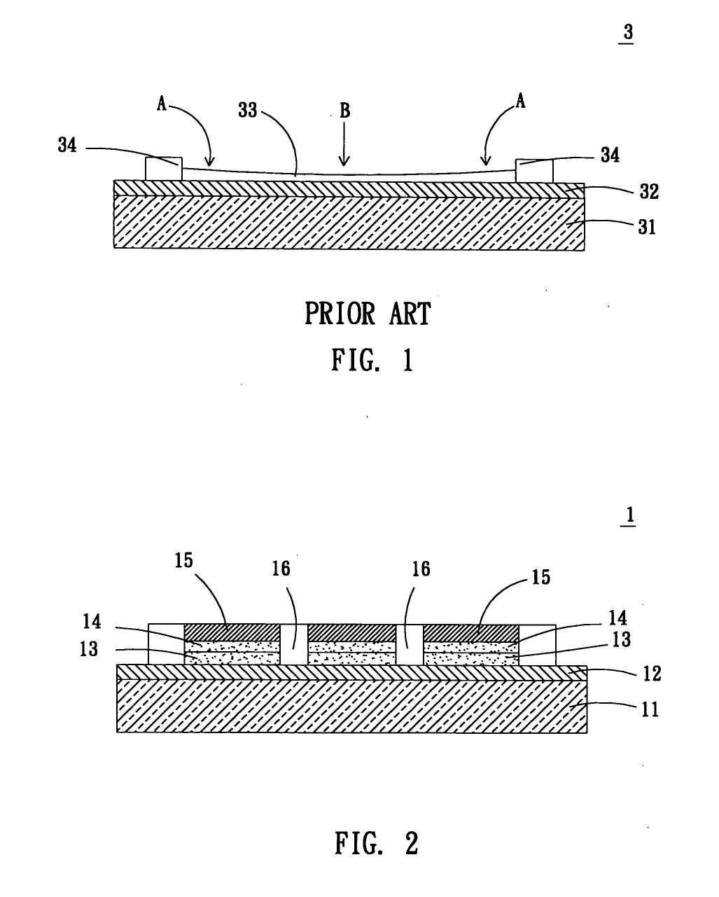

The surface-activation agent is easily dissolved in water or solvent, so that the surface tension of the solution can be reduced. Thus, as shown in FIG. 3, the hole buffer layer 23 of the embodiment has better planarity then that of the conventional hole buffer layer (as shown in FIG. 1).

In brief, the organic electroluminescent device of the invention comprises a hole buffer layer, which comprises a surface-activation agent. Comparing to the prior art, the invention can reduce the surface tension of the hole buffer layer. When forming the hole buffer layer on the electrode layer, the surface-activation agent can enhance the planarity of the hole buffer layer. Thus, the brightness uniformity of the organic electroluminescent device is improved, and the production yield of the organic electroluminescent device is increased. In addition, the manufacturing process is simpler and cheaper, so that the invention is suitable for mass production.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An organic electroluminescent device, comprising:
a transparent substrate;
a first electrode disposed on the transparent substrate;
a hole buffer layer, which comprises a surface-activation agent and is disposed on the first electrode;
an organic electroluminescent layer disposed on the hole buffer layer; and
a second electrode disposed on the organic electroluminescent layer.

2. The organic electroluminescent device of claim 1, further comprising:
a separating portion disposed on the first electrode to divide the hole buffer layer and the organic electroluminescent layer into a plurality of pixels.

3. The organic electroluminescent device of claim 1, wherein the hole buffer layer comprises a hole-injecting layer and/or a hole-transporting layer.

4. The organic electroluminescent device of claim 1, wherein the material of the hole buffer layer is a conductive polymeric material and/or a conductive small molecule material.

5. The organic electroluminescent device of claim 4, wherein the material of the hole buffer layer is at least one selected from the group consisting of poly(3,4-ethylenedioxythiophene) (PEDOT), polyaniline (PANI), poly(N-vinylcarbazole) (PVK), copper phthalocyanine (CuPc), 4,4′,4′-tris(1-naphthylphenylamino)triphenylamine (1-TNATA), 4,4′,4″-tris-N-3-methylphenyl-N-phenyl-amino)-triphenylamine (m-MTDATA), 4,4′-bis[N-(1-naphthyl)-N-phenylamino]biphenyl (NPB), 4,4′-bis[N-(3-methylphenyl)-N-phenyl-amino]-biphenyl (TPD), triphenylamine tetramer (TPTE), spiro-linked TAD (spiro-TAD), 1,1-bis(4-di-p-tolylaminophenyl)-4-phenylcyclohexane (TPAC), and 2,5-diphenyl-1,3,4-oxadiazole (PPD).

6. The organic electroluminescent device of claim 1, wherein the surface-activation agent is an anion surface-activation agent or a cation surface-activation agent.

7. The organic electroluminescent device of claim 1, wherein the surface-activation agent is an amphoteric surface-activation agent.

8. The organic electroluminescent device of claim 1, wherein the surface-activation agent is a nonionic surface-activation agent.

9. The organic electroluminescent device of claim 1, wherein the hydrophile-lipophile balance (HLB) value of the surface-activation agent is greater than or equal to 8.

10. The organic electroluminescent device of claim 1, wherein the first electrode is a conductive metal oxide electrode layer, and the second electrode is an electrode layer made of at least one material selected from the group consisting of aluminum (Al), calcium (Ca), magnesium (Mg), indium (In), tin (Sn), manganese (Mn), silver (Ag), gold (Au), and magnesium alloys.

11. An electrode substrate, comprising:
a transparent substrate;
an electrode layer disposed above the transparent substrate; and
a hole buffer layer, which comprises a surface-activation agent and is disposed above the electrode layer.

12. The electrode substrate of claim 11, further comprising:
a separating portion disposed on the electrode layer to divide the hole buffer layer into a plurality of pixels.

13. The electrode substrate of claim 11, wherein the hole buffer layer comprises a hole-injecting layer and/or a hole-transporting layer.

14. The electrode substrate of claim 11, wherein the material of the hole buffer layer is a conductive polymeric material and/or a conductive small molecule material.

15. The electrode substrate of claim 14, wherein the material of the hole buffer layer is at least one selected from the group consisting of poly(3,4-ethylenedioxythiophene) (PEDOT), polyaniline (PANI), poly(N-vinylcarbazole) (PVK), copper phthalocyanine (CuPc), 4,4′,4′-tris(1-naphthylphenylamino)triphenyl amine (1-TNATA), 4,4′,4″-tris-N-3-methylphenyl-N-phenyl-amino)-triphenylamine (m-MTDATA), N,N′-di-1-naphthyl-N,N′-diphenyl-1,1′-biphenyl-1,1′-biphenyl-4,4′-diamine (NPB), 4,4′-bis[N-(3-methylphenyl)-N-phenyl-amino]-biphenyl (TPD), triphenylamine tetramer (TPTE), spiro-linked TAD (spiro-TAD), 1,1-bis(4-di-p-tolylaminophenyl)-4-phenylcyclohexane (TPAC), and 2,5-diphenyl-1,3,4-oxadiazole (PPD).

16. The electrode substrate of claim 11, wherein the surface-activation agent is an anion surface-activation agent or a cation surface-activation agent.

17. The electrode substrate of claim 11, wherein the surface-activation agent is an amphoteric surface-activation agent.

18. The electrode substrate of claim 11, wherein the surface-activation agent is a nonionic surface-activation agent.

19. The electrode substrate of claim 11, wherein the hydrophile-lipophile balance (HLB) value of the surface-activation agent is greater than or equal to 8.

20. The electrode substrate of claim 11, wherein the electrode layer is a conductive metal oxide electrode layer.
